(19) United States
(12) Patent Application Publication
(10) Pub. No.: US 2012/0234241 A1
(43) Pub. Date: Sep. 20, 2012

(54) MICROWAVE PLASMA DEPOSITION DEVICE

(76) Inventors: I-Nan LIN, New Taipei City (TW); Ton-Rong Tseng, New Taipei City (TW)

(21) Appl. No.: 13/191,218

(22) Filed: Jul. 26, 2011

(30) Foreign Application Priority Data
Mar. 16, 2011 (TW) 100108913

(51) Int. Cl. C23C 16/511

(52) U.S. Cl. 118/723 ME

(57) ABSTRACT

A microwave plasma deposition device includes: a main chamber; a support disposed in the main chamber for supporting an article to be coated; a resonance chamber fluidly connected to the main chamber and disposed opposite to the support; a microwave plasma generator disposed in the resonance chamber for generating a plasma to travel to the support; a separation cover unit disposed in the main chamber to cover the support and to define a deposition space within the main chamber and around the support, and including a plurality of plasma through holes that connect fluidly the deposition space with a remaining part of the main chamber to permit the plasma to enter the deposition space; and a precursor supplying device for supplying a precursor to the deposition space.

### CROSS-REFERENCE TO RELATED APPLICATION

This application claims priority of Taiwanese application no. 100108913, filed on Mar. 16, 2011.

### BACKGROUND OF THE INVENTION

1. Field of the Invention

This invention relates to a microwave plasma deposition device, more particularly to a microwave plasma deposition device for forming a silicon film with a relatively large area.

2. Description of the Related Art

Referring to FIG. 1, a conventional microwave plasma deposition device for coating a film on an article includes a main chamber 11, a support 12, and a microwave plasma generator 14.

The main chamber 11 has a chamber room 201, and a pressure and a gas atmosphere inside the chamber room 201 can be varied such as by vacuum-pumping or introducing gases. The support 12 is disposed on a bottom side of the chamber room 201 for supporting an article (not shown) to be coated. The microwave plasma generator 14 is disposed at a top side of the chamber room 201, and is used for activating a plasma-forming gas supplied to the chamber room 201 to generate a plasma.

For coating a film on an article using the conventional microwave plasma deposition device, the article is disposed on the support 12, the vacuum degree and the gas atmosphere inside the chamber room 201 are adjusted to predetermined levels, followed by introducing a microwave using the microwave plasma generator 14 to ignite a plasma. Thereafter, a precursor supplied to the vicinity of the support 12 interacts with the plasma to form a film on the article.

However, when coating a relatively large film on an article, especially when coating a silicon film to form a solar cell panel using the conventional microwave plasma deposition device, the flatness and fineness of the coated film is not sufficient. This is because the film is formed by interaction between the plasma and the precursor in the vicinity of the support 12, and because particles are likely to be formed in the plasma while the plasma travels to the support 12 due to phenomena, such as reversal of the excited state of the plasma to an initial state thereof, recombination of ions and electrons, etc.

Therefore, the conventional microwave plasma deposition device needs further improvement.

### SUMMARY OF THE INVENTION

Therefore, an object of the present invention is to provide a microwave plasma deposition device that can overcome the aforesaid drawbacks associated with the prior art.

According to researches, the dissociation energy for a silicon compound (for example, the energy for dissociation of SiCl₄ into Si ions) need not be very high. When the silicon compound serves as a precursor to interact with a low energy portion of the plasma (such as a remote plasma, or a corona plasma, especially when it is used to form a large silicon film, the flatness and fineness of the film can be improved.

Accordingly, a microwave plasma deposition device of this invention comprises:

a main chamber;

a support disposed in the main chamber for supporting an article to be coated;

a resonance chamber fluidly connected to the main chamber and disposed opposite to the support;

a microwave plasma generator disposed in the resonance chamber for generating a plasma to travel to the support;

a separation cover unit disposed in the main chamber to cover the support and to define a deposition space within the main chamber and around the support, and

including a plurality of plasma through holes that connect fluidly the deposition space with a remaining part of the main chamber to permit the plasma to enter the deposition space; and

a precursor supplying device for supplying a precursor to the deposition space.

### BRIEF DESCRIPTION OF THE DRAWINGS

Other features and advantages of the present invention will become apparent in the following detailed description of the preferred embodiment of the invention, with reference to the accompanying drawings, in which:

FIG. 1 is a perspective cutaway view of a conventional microwave plasma deposition device;

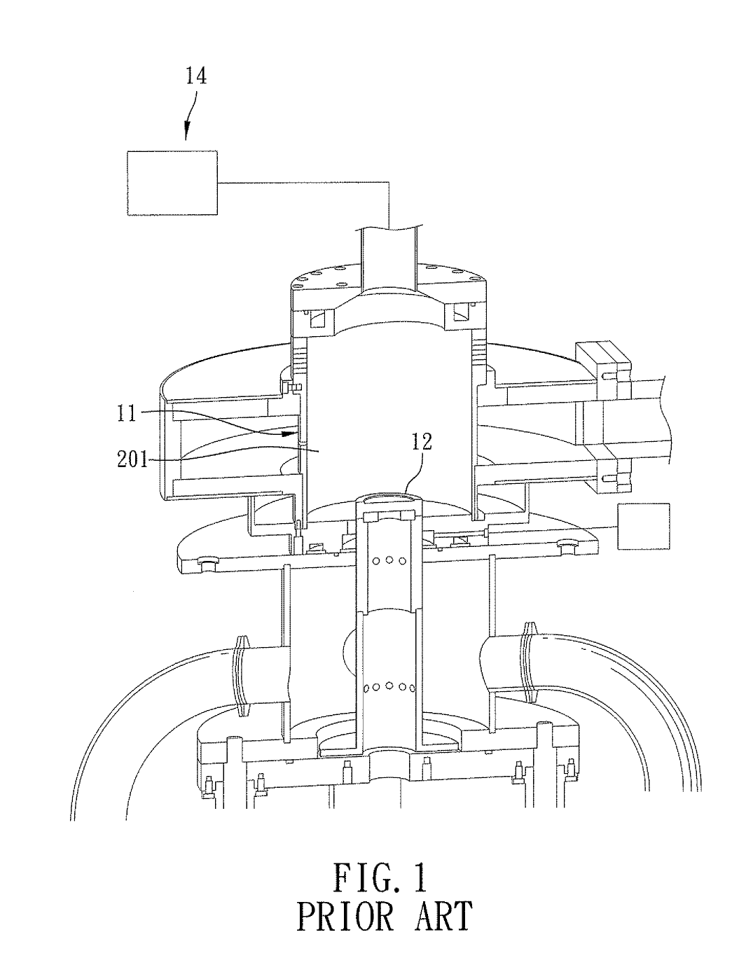

FIG. 2 is a perspective cutaway view illustrating the preferred embodiment of a microwave plasma deposition device according to this invention; and

FIG. 3 is a fragmentary enlarged cross-sectional view illustrating a separation cover unit in the microwave plasma deposition device of FIG. 2.

### DETAILED DESCRIPTION OF THE PREFERRED EMBODIMENT

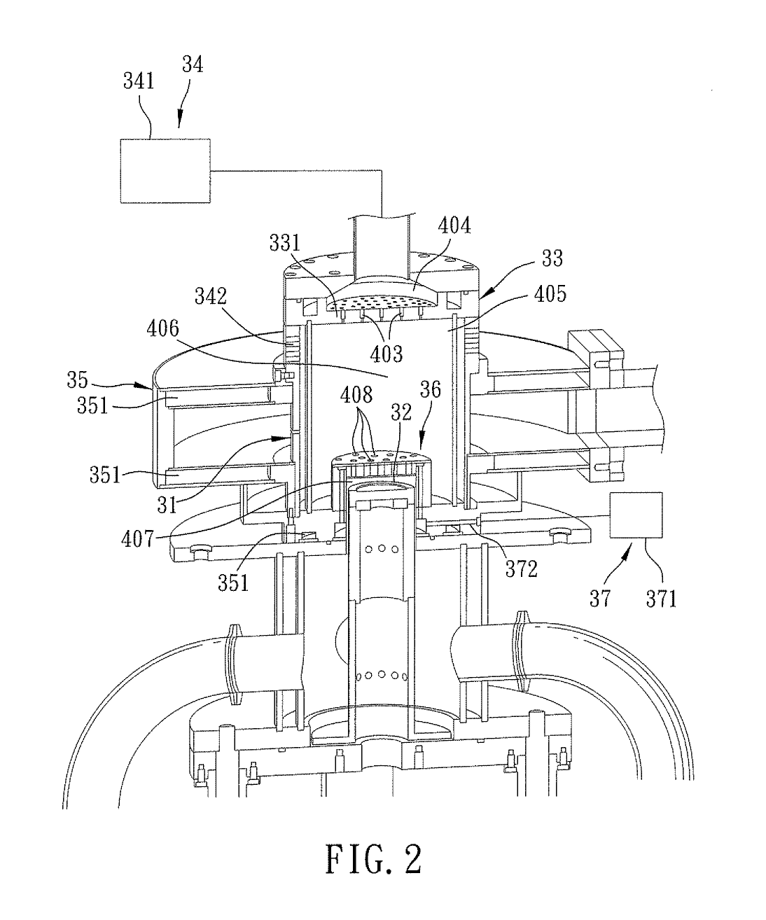

Referring to FIG. 2, the preferred embodiment of a microwave plasma deposition device according to this invention comprises a main chamber 31, a support 32, a resonance chamber 33, a microwave plasma generator 34, a cooling device 35, a separation cover unit 36, and a precursor supplying device 37. The microwave plasma deposition device supplies a remote plasma to evenly form a uniform film on an article to be coated.

The main chamber 31 is an upright chamber. The pressure and the atmosphere inside the main chamber 31 may be varied in a known manner, such as by vacuum-pumping or introducing gases.

The support 32 is disposed in a bottom part of the main chamber 31 for supporting an article (not shown) to be coated.

The resonance chamber 33 is fluidly connected to a top side of the main chamber 31, and is disposed oppositely to the support 32. The resonance chamber 33 includes a perforated partition wall 331 having a plurality of through holes 403 and dividing the resonance chamber 33 into a gas inlet region 404 and a plasma generation region 405. The plasma generation region 405 is connected fluidly to the gas inlet region 404 through the through holes 403 of the perforated partition wall 331, and is connected fluidly to the main chamber 31 oppositely of the gas inlet region 404. In an embodiment, the resonance chamber 33 confines an interior space having a radius of 65 mm and a height of 153 mm. The through holes 403 of the perforated partition wall 331 have a through-hole diameter of 3˜5 mm, and are arranged regularly and spaced apart by a distance of 8˜12 mm.

The microwave plasma generator 34 is disposed in the resonance chamber 33 for generating a plasma to travel to the support 32. The microwave plasma generator 34 includes a gas supplying unit 341 for introducing a plasma-forming gas into the gas inlet region 404, and an annular waveguide 342 connected to the plasma generation region 405 to emit microwave to interact with the plasma-forming gas. The annular waveguide 342 may have a rectangular cross section. The radius of the annular waveguide 342 may be about 110 mm. The cooling device 35 includes a plurality of cooling jackets 351 surrounding the main chamber 31 and the resonance chamber 33 for circulation of cooling water. With the cooling device 35, generation of high temperature heat, due to a high power needed to ignite the plasma under an atmosphere of 400˜760 torr, may be prevented.

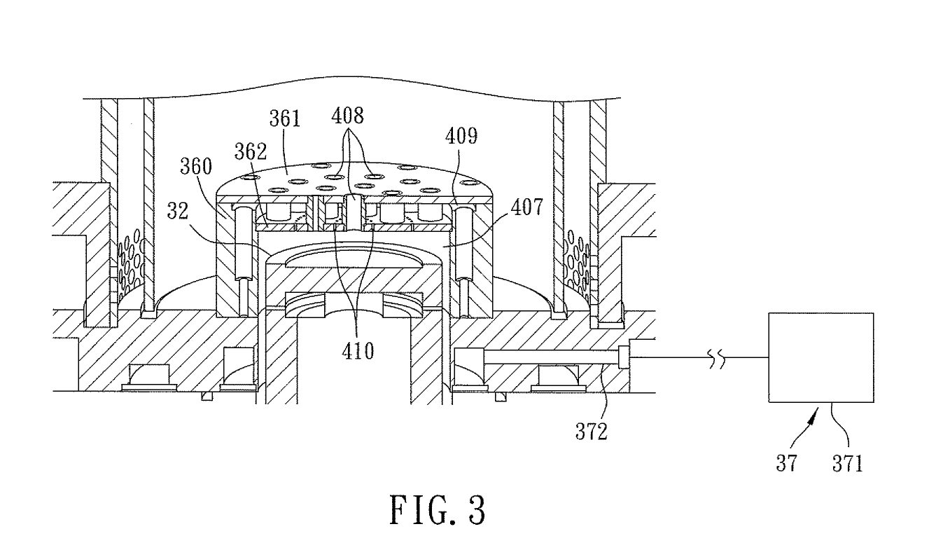

Further referring to FIG. 3, the separation cover unit 36 is disposed in the main chamber 31 to cover the support 32 and to define a deposition space 407 within the main chamber 31 and around the support 32. The separation cover unit 36 includes a surrounding wall 360, an upper wall 361, a lower wall 362, a plurality of plasma through holes 408, a precursor receiving space 409, and a plurality of precursor through holes 410.

The surrounding wall 360 surrounds the support 32. The upper wall 361 is disposed on top of the surrounding wall 360. The lower wall 362 is disposed below the upper wall 361 and is spaced apart from the support 32. The plasma through holes 408 extend through the upper and lower walls 361, 362, and connect fluidly the deposition space 407 with a plasma travelling space 406 in a remaining part of the main chamber 31 to permit the plasma, especially a remote plasma that travels through the plasma travelling space 406, to enter the deposition space 407. The precursor receiving space 409 is disposed between the upper and lower walls 361, 362 and is connected to the precursor supplying device 37 that is used for supplying a precursor. The precursor through holes 410 extend through the lower wall 362, and connect fluidly the precursor receiving space 409 to the deposition space 407. Accordingly, the precursor from the precursor supplying device 37 can be supplied to the deposition space 407 through the precursor receiving space 409 and the precursor through holes 410 to interact with the remote plasma. The plasma through holes 408 have a through-hole size of 3˜5 mm, and are spaced apart by a distance of 8˜12 mm. The precursor through holes 410 have a through-hole size of 1˜3 mm, and are spaced apart by a distance of 5˜12 mm. The plasma through holes 408 and the precursor through holes 410 are arranged in annular rows in the lower wall 362. The annular rows of the plasma through holes 408 alternate with the annular rows of the precursor through holes 410. Each row of the plasma through holes 408 is spaced apart from an adjacent row of the precursor through holes 410 by a distance of 5˜12 mm.

The precursor supplying device 37 includes a precursor source 371 for supplying the precursor, and a conduit 372 for connecting the precursor source 371 with the precursor receiving space 409.

For growing a film using the microwave plasma deposition device of this invention, an article is disposed on the support 32, and the main chamber 31 is vacuumed to have a predetermined atmospheric pressure thereinside. Thereafter, a predetermined plasma-forming gas is supplied from the gas supplying unit 341 to the gas inlet region 404, and then travels to the plasma generation region 405 through the through holes 403 of the perforated partition wall 331. The plasma-forming gas in the plasma generation region 405 is ignited by the microwave emitted from the annular waveguide 342 to generate a plasma. The plasma travels toward the support 32. When the plasma travels to the separation cover unit 36, only the remote plasma that has a relatively low energy can pass through the plasma through holes 408 and into the deposition space 407. In the meantime, the precursor from the precursor source 371 is supplied to the precursor receiving space 409 via the conduit 372, and then flows to the deposition space 407 through the precursor through holes 410. The remote plasma and the precursor interact with each other in the deposition space 407 to form a film on the article on the support 32. The coated film has improved flatness and fineness, and the microwave plasma deposition device of this invention is suitable for forming a relatively large area film on a solar cell panel.

While the present invention has been described in connection with what is considered the most practical and preferred embodiment, it is understood that this invention is not limited to the disclosed embodiment but is intended to cover various arrangements included within the spirit and scope of the broadest interpretations and equivalent arrangements.

What is claimed is:

1. A microwave plasma deposition device, comprising:
a main chamber;
a support disposed in said main chamber for supporting an article to be coated;
a resonance chamber fluidly connected to said main chamber and disposed opposite to said support;
a microwave plasma generator disposed in said resonance chamber for generating a plasma to travel to said support;
a separation cover unit disposed in said main chamber to cover said support and to define a deposition space within said main chamber and around said support, and including a plurality of plasma through holes that connect fluidly said deposition space with a remaining part of said main chamber to permit the plasma to enter said deposition space; and
a precursor supplying device for supplying a precursor to said deposition space.

2. The microwave plasma deposition device of claim 1, wherein said separation cover unit further includes a precursor receiving space connected to said precursor supplying device, and a plurality of precursor through holes connecting fluidly said precursor receiving space to said deposition space.

3. The microwave plasma deposition device of claim 2, wherein said separation cover unit further includes a surrounding wall surrounding said support, an upper wall disposed on top of said surrounding wall and facing said resonance chamber, and a lower wall disposed below said upper wall and spaced apart from said support, said precursor receiving space being formed between said upper and lower walls, said precursor through holes extending through said lower wall, said plasma through holes extending through said upper and lower walls.

4. The microwave plasma deposition device of claim 3, wherein said plasma through holes and said precursor through holes are arranged in annular rows in said lower wall, said annular rows of said plasma through holes alternating with said annular rows of said precursor through holes.

5. The microwave plasma deposition device of claim 1, further comprising a cooling device surrounding said main chamber and said resonance chamber.

6. The microwave plasma deposition device of claim 1, wherein said resonance chamber includes a perforated partition wall dividing said resonance chamber into a gas inlet region, and a plasma generation region that is connected fluidly to said gas inlet region through said perforated partition wall and that is connected fluidly to said main chamber oppositely of said gas inlet region, said microwave plasma generator including a gas supplying unit for introducing a plasma-forming gas into said gas inlet region, and an annular waveguide connected to said plasma generation region to emit microwave to interact with the plasma-forming gas.
